(19) United States
(12) Patent Application Publication
(10) Pub. No.: US 2011/0036708 A1
(43) Pub. Date: Feb. 17, 2011

(54) MAGNETRON SPUTTERING DEVICE

(75) Inventors: CHIA-YING WU, Tu-Cheng (TW); CHING-CHOU CHANG, Tu-Cheng (TW)

Correspondence Address: Altis Law Group, Inc.;ATTN: Steven Reiss, 288 SOUTH MAYO AVENUE, CITY OF INDUSTRY, CA, 91789, US

(73) Assignee: HON HAI PRECISION INDUSTRY CO., LTD., Tu-Cheng (TW)

(21) Appl. No.: 12/649,464

(22) Filed: Dec. 30, 2009

(30) Foreign Application Priority Data
Aug. 14, 2009 (CN) 200910305620.5

(51) Int. Cl. C23C 14/35; C23C 14/58; C23C 14/50

(52) U.S. Cl. 204/298.08; 204/298.17; 204/298.22; 204/298.09; 204/298.15

(57) ABSTRACT

An exemplary magnetron sputtering device includes a target, a magnet arrangement, and a driving system. The target defines a magnet-receiving space therein. The magnet arrangement is received within the magnet-receiving space. The driving system is configured for driving the magnet arrangement to spin and move back and forth.

### BACKGROUND

1. Technical Field

This present disclosure relates to magnetron sputtering devices and, particularly, relates to a magnetron sputtering device having a movable magnet arrangement.

2. Description of Related Art

A magnetron sputtering device includes a tubular target and an arrangement of magnets received within the tubular target. Magnetic fields of the magnets are superposed and produce a superposed magnetic field of which the magnetic density around the outer surface of the tubular target is not uniform. As such, more atoms are accelerated to portions of the outer surface of the tubular target where the magnetic density is high and less reaches to other portions where the magnetic density is low. Therefore, the portions of the tubular target corresponding to the high magnetic density may be exhausted while the other portions corresponding to the low magnetic density may have residua that can not be used. The efficiency of the tubular target is low.

Therefore, it is desirable to provide a magnetron sputtering device, which can overcome the above-mentioned problems.

### BRIEF DESCRIPTION OF THE DRAWING

The FIGURE is a cross-sectioned, schematic view of a magnetron sputtering device, according to an exemplary embodiment.

### DETAILED DESCRIPTION

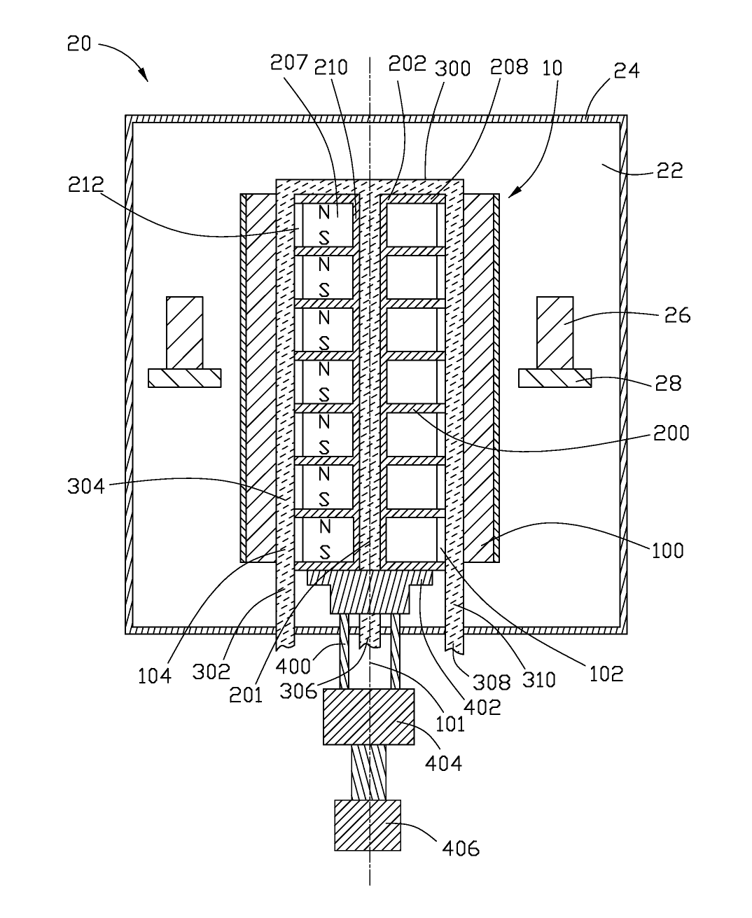

Referring to FIG. 1, a magnetron sputtering device 20, according to an exemplary embodiment, includes a reactive container 24, a target assembly 10, and a number of holders 28. The reactive container 24 defines a reactive chamber 22. The target assembly 10 and the holders 28 are received within the reactive chamber 22. The holders 28 are fixed in place and configured for holding objects 26 to be coated. In particular, in this embodiment, the reactive container 24, the reactive chamber 22, and the target assembly 10 (see below) are substantially cylindrical and substantially symmetrical about a central axis 101. That is, the target assembly 10 is coaxially positioned within the reactive chamber 22. The holders 28 are arranged around the target assembly 10. However, it should be understood that the reactive container 24, the reactive chamber 22, and the target assembly 10 are not limited to the shape and arrangement described in this embodiment. In other alternative embodiments, the reactive container 24 and the reactive chamber 22 can be cubic or other geometrical shapes. The target assembly 10 can be positioned at a corner of the reactive chamber 22.

The target assembly 10 includes a target 100, a magnetic arrangement 200, a cooling system 300, and a driving system 400. The target 100 defines a magnet-receiving space 102 therethrough. The magnetic arrangement 200 is received within the magnet-receiving space 102. The cooling unit 300 is configured for cooling the target 100. The driving system 400 is configured for driving the magnetic arrangement 200 to spin about the central axis 101 and move along the central axis 101 within the magnet-receiving space 102.

In particular, the target 100 is substantially tubular and symmetrical about the central axis 101. Accordingly, the magnet-receiving space 102 is substantially cylindrical.

The magnetic arrangement 200 includes a bracket 202 and a number of magnets 207. The bracket 202 includes a connecting tube 210 and a number of supporting plates 208. The connecting tube 210 is also substantially symmetrical about the central axis 101 and defines a first flowing space 201 therethrough. The first flowing space 201 is substantially cylindrical and symmetrical about the central axis 101. The supporting plates 208 are annular and substantially identical to each other in shape and size. The inner diameters of the supporting plates 208 are substantially equal to or slightly less than the outer diameter of the connecting tube 210. The outer diameters of the supporting plates 208 are smaller than the diameter of the magnet-receiving space 102. The magnets 207 are also annular and substantially identical to each other in shape and size. The inner diameters of the magnets 207 are substantially equal to or slightly larger than the outer diameter of the connecting tube 210. The outer diameters of the magnets 207 are smaller than the diameter of the magnet-receiving space 102. The supporting plates 208 and the magnets 207 surround the connecting tube 210 and arranged along the lengthwise direction of the connecting tube 210 in an alternating fashion. As such, each two supporting plates 208 are spaced from each other and form a positioning space 212 in which a corresponding magnet 207 is accommodated. The magnets 207 are positioned so that opposite magnetic poles of each two adjacent magnets 207 face each other. Magnetic fields of the magnets 207 are superposed to form a superposed magnetic field (not shown). The target 100 and the magnet arrangement 200 cooperatively define a second flowing space 104 therebetween.

The cooling system 300 includes a pipe structure 302 and a cooling liquid 304 flowing through the pipe 302. The pipe 302 includes an inlet 306 and an outlet 308. The pipe structure 302 extends from the inlet 306, through the first flowing space 201 and the second flowing space 104, and ends at the outlet 308. A section of the pipe structure 302 in the second flowing space 104 can be annular and wraps around the target 100. The pipe structure 302 defines an inner flowing space 310 therein. The cooling liquid 304 flows from the inlet 306, though the inner flowing space 310, and out of the inner flowing space 310 via the outlet 308, taking heat generated by the target 100 away. It should be understood that if an amount of heat generated by the target 100 is within an acceptable range, the cooling system 300 can be omitted in other alternative embodiments.

The driving system 400 includes a connecting member 402, a motor 44, and a cylinder 406. The connecting member 402 is connected to the bracket 202 and protrudes an annular connecting portion (not labeled) through a corresponding annular opening (not labeled) defined though the reactive container 24. The motor 104 is coupled to the connecting member 402 and configured for rotating the connecting member 402. The cylinder 406 is coupled to the motor 404 and configured for driving the motor 404 back and forth along the central axis 101. As such, the magnet arrangement 200 and the superposed magnetic field can be driven to spin and move back and forth along the central axis 101. As a result, uniformity of the magnetic density of the magnet arrangement 200 around the outer surface of the target 100 is improved.

It should be understood that the driving system 400 should not be limited to this embodiment. In other alternative embodiments, the connecting member 402 can be directly coupled to the cylinder 406 and the cylinder 406 is coupled to the motor 404. Also, the motor 404 and the cylinder 406 can be received within the reactive chamber 22.

While various exemplary and preferred embodiments have been described, it is to be understood that the disclosure is not limited thereto. To the contrary, various modifications and similar arrangements (as would be apparent to those skilled in the art) are intended to also be covered. Therefore, the scope of the appended claims should be accorded the broadest interpretation so as to encompass all such modifications and similar arrangements.

What is claimed is:

1. A magnetron sputtering device, comprising:
a target defining a magnet-receiving space therein;
a magnet arrangement received within the magnet-receiving space; and
a driving system configured for driving the magnet arrangement to spin about an axis and move along the axis.

2. The magnetron sputtering device of claim 1, wherein the target is substantially tubular, the magnet-receiving space is generally cylindrical, and the magnet arrangement is substantially cylindrical, the target, the magnet-receiving space, and the magnet-arrangement being generally symmetrical about a central axis.

3. The magnetron sputtering device of claim 2, wherein the magnet arrangement comprises a bracket and a plurality of annular magnets, the bracket comprising a central tube and a plurality of annular supporting plates, the supporting plates and the magnets surrounding the central tube and arranged along a lengthwise direction of the tube in an alternating fashion, each two adjacent supporting plates defining a positioning space in which a corresponding magnet is fittingly accommodated, opposite magnetic poles of two adjacent magnets facing each other.

4. The magnetron sputtering device of claim 1, wherein the driving system comprises a connecting member, a motor, and a cylinder, the connecting member being connected to the magnet arrangement, the motor being coupled to the connecting member and configured for driving the magnet arrangement to spin about the axis, the cylinder being coupled to the motor and configured for driving the magnet arrangement to move along the axis.

5. The magnetron sputtering device of claim 1, further comprising a cooling system for cooling down the target.

6. The magnetron sputtering device of claim 5, wherein the cooling system comprises a pipe structure and a cooling liquid circulating through the pipe structure.

7. The magnetron sputtering device of claim 6, wherein the magnet arrangement defines a first flowing space therein, the magnet-receiving space and the magnet arrangement cooperatively defining a second flowing space therebetween, the pipe structure extending from an inlet, through the first flowing space and the second flowing space, to an outlet.

8. The magnetron sputtering device of claim 1, further comprising a reactive container, the reactive container defining a reactive chamber, the target, the magnet arrangement, and the driving system being accommodated within the chamber.

9. The magnetron sputtering device of claim 1, further comprising a plurality of holders, the holders being arranged around the target and configured for holding objects to be coated.
